(19) United States
(12) Patent Application Publication
(10) Pub. No.: US 2002/0017458 A1
(43) Pub. Date: Feb. 14, 2002

(54) Sputtering target with lowered oxygen content

(75) Inventors: Satoru Kobayashi, Tokyo-To (JP); Yoshihiro Sera, Tokyo-To (JP); Norioki Ikeda, Tokyo-To (JP); Masato Imamura, Tokyo-To (JP); Shuji Shihara, Tokyo-To (JP); Hiroyuki Sakai, Tokyo-To (JP)

Correspondence Address: Richard L. Byrne, 700 Koppers Building, 436 Seventh Avenue, Pittsburgh, PA, 15219-1818, US

(73) Assignee: MITSUI MINING & SMELTING CO., LTD.

(21) Appl. No.: 09/768,702

(22) Filed: Jan. 24, 2001

(30) Foreign Application Priority Data
Jan. 27, 2000 (JP) 2000-18520
Sep. 1, 2000 (JP) 2000-265607

(51) Int. Cl. C23C 14/32; C23C 14/00; C23C 14/34

(52) U.S. Cl. 204/298.13; 204/192.2; 204/298.12; 204/192.15

(57) ABSTRACT

A sputtering target with a lowered oxygen content is provided which can prevent a deterioration in properties of a magnetic film caused by unavoidably included oxygen present in an alloy material system. The sputtering target contains an oxygen scavenger comprising an element capable of reducing metal components constituting the sputtering target, the lowered oxygen content of the sputtering target having been achieved by the oxygen scavenger.

### TECHNICAL FIELD

The present invention relates to a sputtering target for use in the formation of a thin film by sputtering, and more particularly to a sputtering target with a lowered oxygen content.

### BACKGROUND ART

A target material composed of a Co—Cr-base, Co—Ni-base, or Co—Ni—Cr-base alloy has hitherto been industrially used as a sputtering target for the formation of a thin film, such as a magnetic film, by sputtering.

All of the Co—Cr-base, Co—Ni-base, and Co—Ni—Cr-base alloys are rollable, and, thus, a cast ingot produced by melting and casting can be relatively easily rolled to a predetermined thickness.

In the sputtering targets of alloy systems as described above, oxygen is unavoidably included in the step of the preparation of the starting material or in the step of the production of the target. Up to now, attention has not been always fully paid to the presence of oxygen unavoidably included in the alloy system and the regulation of the content of oxygen in the alloy system.

The present inventor has found that, in the above-described sputtering target materials for the formation of thin films, such as magnetic films, the properties of the magnetic films, particularly magnetic properties, are deteriorated by oxygen unavoidably included in the alloy material system.

### DISCLOSURE OF THE INVENTION

The present invention has been made with a view to solving the above problems of the prior art, and it is an object of the present invention to provide a sputtering target with a significantly lowered content of included oxygen causative of a deterioration in the properties of magnetic films.

In order to attain the above object of the present invention, there is provided a sputtering target with a lowered oxygen content, said sputtering target containing an oxygen scavenger comprising an element capable of reducing metal components constituting the sputtering target, the lowered oxygen content of the sputtering target having been achieved by the oxygen scavenger.

According to a preferred embodiment of the present invention, the content of oxygen in the sputtering target is not more than 500 ppm, more preferably not more than 300 ppm, particularly preferably not more than 10 ppm.

According to the present invention, the oxygen scavenger is preferably at least one member selected from the group consisting of group 4A, 3B, and 4B elements, more preferably at least one member selected from the group consisting of group 4A elements, particularly preferably at least one member selected from the group consisting of titanium, aluminum, boron, and carbon, most preferably titanium.

According to a preferred embodiment of the present invention, melting a starting material for a sputtering target and/or casting the melt involving the addition of the oxygen scavenger is carried out in a CaO crucible. In this case, the oxygen scavenger is most preferably titanium.

The sputtering target with a lowered oxygen content according to the present invention is applicable to an NiFe-base, CoCrPt-base, CoCrPtB-base, CoPt-base, PtMn-base, FeAlSi-base, FeCo-base, or FeMn-base sputtering target.

According to a preferred embodiment of the present invention, the sputtering target is an NiFe-base, Co-base, or Fe-base target with an oxygen content of not more than 10 ppm, more preferably not more than 5 ppm.

According to a preferred embodiment of the present invention, the concentration of the residual oxygen scavenger in the sputtering target is not more than 200 ppm, preferably not more than 100 ppm, more preferably not more than 50 ppm.

### BEST MODE FOR CARRYING OUT THE INVENTION

The sputtering target with a lowered oxygen content according to the present invention contains an oxygen scavenger comprising an element capable of reducing metal components constituting the sputtering target, the lowered oxygen content of the sputtering target having been achieved by the oxygen scavenger.

In the sputtering target with a lowered oxygen content according to a preferred embodiment of the present invention, the content of oxygen in the sputtering target is not more than 500 ppm, more preferably not more than 300 ppm, particularly preferably not more than 10 ppm.

The oxygen scavenger according to the present invention is preferably at least one member selected from the group consisting of group 4A, 3B, and 4B elements, more preferably at least one member selected from the group consisting of group 4A elements, particularly preferably at least one member selected from the group consisting of titanium, aluminum, boron, and carbon.

The sputtering target with a lowered oxygen content according to the present invention is applicable to an NiFe-base, CoCrPt-base, CoCrPtB-base, CoPt-base, PtMn-base, FeAlSi-base, FeCo-base, or FeMn-base sputtering target.

According to a preferred embodiment of the present invention, the sputtering target is an NiFe-base, Co-base, or Fe-base target with an oxygen content of not more than 10 ppm, more preferably not more than 5 ppm.

According to a preferred embodiment of the present invention, the concentration of the residual oxygen scavenger in the sputtering target is not more than 200 ppm, preferably not more than 100 ppm, more preferably not more than 50 ppm.

The present invention will be described in more detail with reference to the production process of the present invention.

In the production process according to the present invention, in vacuo, constituent metal materials for constituting a sputtering target are melted, and the melt is then cast. The melting-casting process per se may be carried out by a conventional process. After casting, the cast ingot thus obtained is optionally rolled, followed by machining (for example, cutting) to provide a predetermined sputtering target.

The sputtering target with a lowered oxygen content according to the present invention is applicable to an NiFe-base, CoCrPt-base, CoCrPtB-base, CoPt-base, PtMn-base, FeAlSi-base, FeCo-base, or FeMn-base sputtering target. According to a preferred embodiment of the present invention, the sputtering target is an NiFe-base, Co-base, or Fe-base target.

Preferred production processes will be described for each type of the alloy system.

In the case of an NiFe-base alloy system, the step of melting and casting is carried out, for example, under a vacuum of not more than 3×10⁻⁴ Torr. The resultant cast ingot is rolled at a temperature of about 1,100° C. to provide a rolled plate which is then cut to a product size, followed by machining such as lathing or milling. Thus, a sputtering target is produced.

In the case of a CoCrPt-base alloy system, the step of melting and casting is carried out, for example, under a vacuum of not more than 3×10⁻² Torr. The resultant cast ingot is rolled at a temperature of about 1,100 to 1,200° C. to provide a rolled plate which is then cut to a product size, followed by machining such as lathing or milling. Thus, a sputtering target is produced.

In the case of a PtMn-base alloy system, the step of melting and casting is carried out, for example, under a vacuum of not more than 3×10⁻² Torr. The resultant cast ingot is subjected to machining, such as lathing or milling, to produce a sputtering target. This sputtering target is generally joined to a predetermined backing plate.

In the sputtering target according to the present invention, an oxygen scavenger comprising an element capable of reducing metal components for constituting the sputtering target is added in the step of melting and casting. A lowering in oxygen content has been achieved by this oxygen scavenger.

The oxygen scavenger added is preferably at least one member selected from the group consisting of group 4A, 3B, and 4B elements, more preferably at least one member selected from the group consisting of group 4A elements, particularly preferably at least one member selected from the group consisting of titanium, aluminum, boron, and carbon. According to the present invention, the oxygen scavenger is most preferably titanium.

According to the present invention, in the step of melting and casting, in particular, when the base metal in the melting is iron, it is considered that the presence of an oxygen scavenger, for example, titanium, permits the following reaction to proceed in the molten metal: 2/3Fe₂O₃+Ti=TiO₂+4/3Fe. TiO₂ floats, on the surface of a molten metal, as dross (a scum component of oxides) which, therefore, can be effectively removed.

The present inventor has found that the oxygen content can be further lowered by carrying out the step of melting (dissolution) and/or casting in a CaO crucible. The present inventor has further found that the use of a combination of the CaO crucible with titanium among the above-described oxygen scavengers can offer improved oxygen scavenging effect surpassing the expected effect, and, at the same time, can offer desulfurization effect. The development of this advantageous cooperative function and effect attained by the above combination is particularly significant in a PtMn-base sputtering target. It has hitherto been relatively difficult to scavenge oxygen from the PtMn-base sputtering target.

The reason why the above advantageous cooperative function and effect can be developed has not been fully elucidated yet. However, the reason is believed to be as follows, although the present invention is not limited to any theory. Specifically, TiO₂ as a deoxidation product in the molten metal is absorbed in the CaO crucible according to the following reaction formula:

CaO+TiO₂=CaO.TiO₂

At that time, on the wall surface of the crucible, CaO effectively functions to simultaneously cause a desulfurization reaction according to the following reaction formula:

Ti+2CaO+2S =2CaS+TiO₂

The amount of the oxygen scavenger added in the step of melting and casting is properly selected according to the estimated content of dissolved oxygen. In general, however, the amount of the oxygen scavenger added is suitably in the range of 0.001 to 1.0% by weight, preferably in the range of 0.001 to 0.5% by weight, more preferably in the range of 0.001 to 0.5% by weight.

In particular, in the PtMn-base sputtering target, in melting platinum and manganese in the CaO crucible, the addition of titanium preferably in an amount of 0.001 to 3% by weight, more preferably 0.01 to 0.5% by weight, based on the amount of manganese can lower the oxygen content, for example, to not more than 50 ppm. Further, in this case, the amount of residual titanium can be reduced to not more than 200 ppm.

According to the present invention, the addition of the oxygen scavenger in the above amount range permits the content of oxygen in the sputtering target to be regulated to not more than 500 ppm, more preferably not more than 300 ppm, particularly preferably not more than 10 ppm. Further, in particular, in the case of an NiFe-base, Co-base, or Fe-base sputtering target, the oxygen content can be regulated to not more than 10 ppm, more preferably not more than 5 ppm.

According to the present invention, the concentration of the residual oxygen scavenger in the sputtering target after the removal of oxygen is not more than 200 ppm, preferably not more than 100 ppm, more preferably not more than 50 ppm. The present inventor has found that a concentration of the residual oxygen scavenger of not more than 100 ppm does not adversely affect the properties of the sputtering target.

### EXAMPLES

The following examples further illustrate the present invention, but should not be construed as limiting the present invention.

### Example 1

### Production of NiFe-base Sputtering Target with Lowered Oxygen Content

A mass of nickel (5,000.0 g, 20×20×5 mm, 3N5), a mass of iron (1,110.0 g, 15×15×5 mm, 3N5), and a piece of titanium (1.8 g, 5×5×1 mm, 4N) (total weight 6,111.8 g; amount of titanium added 0.05% by weight) were placed in an MgO crucible, and were then melted in a vacuum melting furnace by high frequency melting.

The melting temperature was up to 1450° C., and the system was evacuated to not more than 3×10⁻⁴ Torr. About two hr after the initiation of melting, the melt was cast in a mold which had been previously provided (casting temperature 1360° C.) to prepare an ingot having a size of 150×150×20 t.

This ingot was heated at 1100° C. for one hr, and then rolled. The rolling was carried out by four passes for one heating, and this was repeated several times to prepare a rolled plate having a predetermined thickness (5 to 7 mm).

A sample having a size of about 5 mm square was taken off from the rolled plate by wire cutting, and applied to gas analysis (non-dispersive infrared absorption analysis with dissolution in inert gas).

As a result, for a sample on melting without the addition of titanium, the oxygen content was 35 ppm, whereas, for the sample on melting with the addition of titanium, the oxygen content was 2.8 ppm. The amount of titanium remaining in the sample was 60 ppm.

### Example 2

### Production of PtMn-base Sputtering Target

A piece of platinum (7,282.0 g, 40×20×1 mm, 3N5), a mass of manganese (2,718.0 g, 15×15×5 mm, 3N), and a piece of titanium (5.0 g, 5×5×1 mm, 3N5) (total weight 10,005.0 g; amount of titanium added 0.05% by weight) were placed in an MgO crucible, and were then melted in a vacuum melting furnace by high frequency melting.

After the evacuation of the furnace, the furnace was filled with argon gas, and raising the temperature was initiated. The furnace was then evacuated in argon atmosphere to not more than 3×10⁻² Torr. About two hr after the initiation of melting, the melt was cast in a mold which had been previously provided (casting temperature 1430° C.) to prepare an ingot having a size of 150 ø×20 t.

A sample having a size of about 5 mm square was taken off from the ingot by wire cutting, and applied to gas analysis (non-dispersive infrared absorption analysis with dissolution in inert gas).

As a result, for a sample on melting without the addition of titanium, the oxygen content was 900 ppm, whereas, for the sample on melting with the addition of titanium, the oxygen content was 250 ppm. The amount of titanium remaining in the sample was 70 ppm.

### Example 3

### Production of CoCrPtTa-base Sputtering Target

A mass of cobalt (866.4 g, 20×20×5 mm, 3N5), a mass of chromium (186.6 g, 30×30×8 mm, 3N5), a piece of platinum (235.8 g, 40×20×1 mm, 3N5), tantalum particles (109.2 g, 5×7×6 mm, 3N5), and a piece of titanium (0.7 g, 5×5×1 mm, 3N5) (total weight 1,398.7 g; amount of titanium added 0.05% by weight) were placed in an MgO crucible, and were then melted in a vacuum melting furnace by high frequency melting.

The melting temperature was up to 1450° C., and the system was evacuated to not more than 3×10⁻⁴ Torr. About two hr after the initiation of melting, the melt was cast in a mold which had been previously provided (casting temperature 1360° C.) to prepare an ingot having a size of 100×150×15 t.

This ingot was heated at 1100° C. for one hr, and then rolled. The rolling was carried out by two passes for one heating, and this was repeated several times to prepare a rolled plate having a predetermined thickness (5 to 7 mm).

A sample having a size of about 5 mm square was taken off from the rolled plate by wire cutting, and applied to gas analysis (non-dispersive infrared absorption analysis with dissolution in inert gas).

As a result, for a sample on melting without the addition of titanium, the oxygen content was 35 ppm, whereas, for the sample on melting with the addition of titanium, the oxygen content was 9 ppm. The amount of titanium remaining in the sample was 70 ppm.

### Example 4

Sputtering targets were produced in the same manner as in Examples 1 to 3, except that a CaO crucible was used instead of the MgO crucible.

For the sputtering targets thus obtained, the oxygen content was as follows, and, for all the targets, the results were satisfactorily good.

NiFe-base target: oxygen content 3 ppm

PtMn-base target: oxygen content 40 ppm

CoCrPtTa-base target: oxygen content 5 ppm

As is apparent also from the results of the examples, the sputtering target according to the present invention contains an oxygen scavenger comprising an element capable of reducing metal components constituting the sputtering target, the lowered oxygen content of the sputtering target having been achieved by the oxygen scavenger. Thus, the present invention can provide a sputtering target with a lowered oxygen content which can prevent a deterioration in properties of magnetic films caused by unavoidably included oxygen present in an alloy material system, and, hence, is very useful from the viewpoint of industry.

What is claimed is:

1. A sputtering target with a lowered oxygen content, said sputtering target containing an oxygen scavenger comprising an element capable of reducing metal components constituting the sputtering target, the lowered oxygen content of the sputtering target having been achieved by the oxygen scavenger.

2. The sputtering target with a lowered oxygen content according to claim 1, which has an oxygen content of not more than 500 ppm, preferably not more than 300 ppm, more preferably not more than 200 ppm, still more preferably not more than 50 ppm, still more preferably not more than 10 ppm.

3. The sputtering target with a lowered oxygen content according to claim 1, wherein the oxygen scavenger is at least one member selected from the group consisting of group 4A, 3B, and 4B elements.

4. The sputtering target with a lowered oxygen content according to claim 1, wherein melting a starting material for a sputtering target and/or casting the melt involving the addition of the oxygen scavenger is carried out in a CaO crucible.

5. The sputtering target with a lowered oxygen content according to claim 1, wherein the oxygen scavenger is at least one member selected from the group consisting of group 4A elements.

6. The sputtering target with a lowered oxygen content according to claim 1, wherein the oxygen scavenger is at least one member selected from the group consisting of titanium, aluminum, boron, and carbon.

7. The sputtering target with a lowered oxygen content according to claim 1, wherein the oxygen scavenger is titanium.

8. The sputtering target with a lowered oxygen content according to claim 1, wherein the sputtering target is an NiFe-base, CoCrPt-base, CoCrPtB-base, CoPt-base, PtMn-base, FeAlSi-base, FeCo-base, or FeMn-base target.

9. The sputtering target with a lowered oxygen content according to claim 1, wherein the sputtering target is an NiFe-base, Co-base, or Fe-base target with an oxygen content of not more than 10 ppm, preferably not more than 5 ppm.

10. The sputtering target with a lowered oxygen content according to claim 1, wherein the concentration of the residual oxygen scavenger in the sputtering target is not more than 200 ppm, preferably not more than 100 ppm, more preferably not more than 50 ppm.
